(19) United States
(12) Patent Application Publication
(10) Pub. No.: US 2025/0228104 A1
(43) Pub. Date: Jul. 10, 2025

(54) DISPLAY DEVICE AND METHOD FOR MANUFACTURING THE DISPLAY DEVICE

(71) Applicant: Samsung Display Co., Ltd., Yongin-si (KR)

(72) Inventor: JONGHWAN CHO, Yongin-si (KR)

(21) Appl. No.: 18/957,887

(22) Filed: Nov. 25, 2024

(30) Foreign Application Priority Data
Jan. 4, 2024 (KR) 10-2024-0001274

(51) Int. Cl. H10K 59/80; H10K 102/00

(52) U.S. Cl. CPC H10K 59/871; H10K 2102/311

(57) ABSTRACT

Provided is a display device including a foldable display panel and a protective member disposed on the display panel. The protective member may include a protective base layer, a hard coating layer, and a protective layer which are sequentially stacked. The protective layer may include a base resin including dodecafluoroheptylacrylate (DFHA) having a degree of polymerization of about 8. The protective layer may include a first compound dispersed in the base resin. The display device may have excellent reliability.

This application claims priority to Korean Patent Application No. 10-2024-0001274, filed on Jan. 4, 2024, and all the benefits accruing therefrom under 35 U.S.C. § 119, the content of which in its entirety is herein incorporated by reference.

### BACKGROUND

### Field

The present disclosure relates to a foldable display device and a method for manufacturing the display device.

### Description of the Related Art

Various display devices such as, for example, televisions, mobile phones, tablet computers, or game consoles are being developed. Recently, flexible display devices including a flexible display panel which is slidable or foldable have been developed. The flexible display devices are foldable, rollable, or bendable unlike rigid display devices. Since some flexible display devices of which shapes are variously transformable may be carried regardless of screen sizes thereof, user convenience is improved. Approaches for maintaining reliability of the flexible display devices in consideration of a user's usage environment are desired.

### SUMMARY

The present disclosure provides a display device having excellent reliability and display quality, and a method for manufacturing the display device.

An embodiment of the inventive concept a display device including a display panel foldable with respect to at least one folding axis, and a protective member disposed on the display panel, wherein the protective member includes a protective base layer, a hard coating layer disposed on the protective base layer, and a protective layer disposed on the hard coating layer. The protective layer includes a base resin including dodecafluoroheptylacrylate (DFHA) having a degree of polymerization of about 8, and a first compound dispersed in the base resin. The first compound includes an azomethine compound.

In an embodiment, a weight ratio of the base resin and the first compound may be about 7:3 to about 9:1.

In an embodiment, the first compound may include a first sub-compound, which is the azomethine compound, and a second sub-compound different from the first sub-compound, and the second sub-compound may include at least one of a benzotriazole-based compound, a cyanoacrylate-based compound, a benzophenone-based compound, a salicylic acid-based compound, a salicylate-based compound, a cinnamate-based compound, an oxanilide-based compound, a polystyrene-based compound, a polyferrocenylsilane-based compound, a methine-based compound, a triazine-based compound, a para-aminobenzoic acid-based compound, a cinnamic acid-based compound, or an urocanic acid-based compound.

In an embodiment, with respect to a total weight of a first weight of the first sub-compound and a second weight of the second sub-compound, the second weight may be greater than the first weight.

In an embodiment, a weight ratio of the first sub-compound and the second sub-compound may be about 1:1.5 to about 1:3.5.

In an embodiment, a thickness of the protective layer may be about 0.08 μm to about 0.12 μm.

In an embodiment, a specular component included (SCI) reflectance of the protective layer may have may be about 0.8 to about 1.8.

In an embodiment, a transmittance of the protective layer may be about 30% or less with respect to light having a wavelength region of about 350 nm to about 410 nm.

In an embodiment, a transmittance of the protective layer may be equal to or less than about 5% with respect to light having a wavelength of about 405 nm.

In an embodiment, the protective base layer may include at least one of polyethyleneterephthalate, polyimide, polyacrylate, polymethylmethacrylate, polycarbonate, polyethylenenaphthalate, polyvinylidenechloride, polyvinylidenedifluoride, polystyrene, or ethylene-vinylalcohol copolymer.

In an embodiment, a thickness of the protective member may be about 60 μm to about 80 μm.

In an embodiment, a refractive index of the base resin may be about 1.2 to about 1.4.

In an embodiment of the inventive concept, a method for manufacturing a display device includes preparing a display panel foldable with respect to at least one folding axis, and supplying a protective member including a protective base layer on the display panel, a hard coating layer disposed on the protective base layer, and a protective layer disposed on the hard coating layer, wherein the supplying of the protective member includes preparing a substrate including the protective base layer and the hard coating layer, and forming a protective layer on the substrate by supplying a base resin including dodecafluoroheptylacrylate having a degree of polymerization of about 8, and a first compound including an azomethine compound, wherein the protective layer includes the first compound dispersed in the dodecafluoroheptylacrylate.

In an embodiment, in the forming of the protective layer, the base resin and the first compound may be supplied at an ion acceleration voltage of about 100 V to about 500 V.

In an embodiment, the forming of the protective layer may include forming a preliminary protective layer by dispersing the first compound in the base resin, and depositing the preliminary protective layer on the substrate, wherein the forming of the preliminary protective layer and the depositing of the preliminary protective layer may be performed in the same operation.

In an embodiment, the forming of the protective layer may be performed at a temperature of about −30° C. to about 10° C.

In an embodiment, a weight ratio of the base resin and the first compound may be about 7:3 to about 9:1.

In an embodiment, the first compound may include a first sub-compound which is the azomethine compound, and a second sub-compound different from the first sub-compound, and the second sub-compound may include at least one of a benzotriazole-based compound, a cyanoacrylate-based compound, a benzophenone-based compound, a salicylic acid-based compound, a salicylate-based compound, a cinnamate-based compound, an oxanilide-based compound, a polystyrene-based compound, a polyferrocenylsilane-based compound, a methine-based compound, a triazine-based compound, a para-aminobenzoic acid-based compound, a cinnamic acid-based compound, or an urocanic acid-based compound.

In an embodiment, a weight ratio of the first sub-compound and the second sub-compound may be about 1:1.5 to about 1:3.5.

In an embodiment, the protective base layer may include at least one of polyethyleneterephthalate, polyimide, polyacrylate, polymethylmethacrylate, polycarbonate, polyethylenenaphthalate, polyvinylidenechloride, polyvinylidenedifluoride, polystyrene, or ethylene-vinylalcohol copolymer.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view illustrating a display device according to an embodiment;

FIG. 1B is a perspective view illustrating a display device according to an embodiment;

FIG. 1C is a plan view illustrating a display device according to an embodiment;

FIG. 1D is a perspective view illustrating a display device according to an embodiment;

FIG. 2A is a perspective view illustrating a display device according to an embodiment;

FIG. 2B is a perspective view illustrating a display device according to an embodiment;

FIG. 2C is a perspective view illustrating a display device according to an embodiment;

FIG. 3 is an exploded perspective view illustrating a display device according to an embodiment;

FIG. 4 is a cross-sectional view illustrating a portion corresponding to line I-I′ in FIG. 3;

FIG. 5 is an enlarged cross-sectional view illustrating region XX′ in FIG. 4;

FIG. 6 is a cross-sectional view illustrating a portion corresponding to line II-II′ in FIG. 3;

FIG. 7A is a flowchart illustrating a method for manufacturing a display device according to an embodiment;

FIG. 7B is a flowchart illustrating a method for manufacturing a display device according to an embodiment; and

FIG. 8 is a diagram schematically illustrating an operation of manufacturing a display device according to an embodiment.

### DETAILED DESCRIPTION

Embodiments of the present disclosure support various modifications various forms, and specific example embodiments will be illustrated in the drawings and described in detail in the text. However, the descriptions are not intended to limit the inventive concept to a specific disclosure form, and the examples provided herein should be understood to include all changes, equivalents, and substitutes included in the spirit and scope of the inventive concept.

In this specification, descriptions of a component (or region, layer, portion, or the like) referred to as “on”, “connected”, or “coupled” to another component means that the component is placed/connected/coupled directly on the other component or a third component can be disposed between the components.

The same reference numerals or symbols refer to the same elements. In some aspects, in the drawings, thicknesses, ratios, and dimensions of components are exaggerated for effective description of technical content. “And/or” includes all combinations of one or more that the associated elements may define.

Terms such as, for example, first and second may be used to describe various components, but the components should not be limited by the terms. These terms are used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In some aspects, terms such as, for example, “below”, “lower”, “above”, and “upper” are used to describe the relationship between components illustrated in the drawings. The terms are relative concepts and are described based on the directions indicated in the drawings.

Terms such as, for example, “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

Unless otherwise defined, all terms (including technical and scientific terms) used in this specification have the same meaning as commonly understood by one of ordinary skill in the art to which this invention belongs. Terms defined in commonly used dictionaries should be interpreted as having a meaning consistent with the meaning having in the context of the related technology, and should not be interpreted as too ideal or too formal unless explicitly defined here.

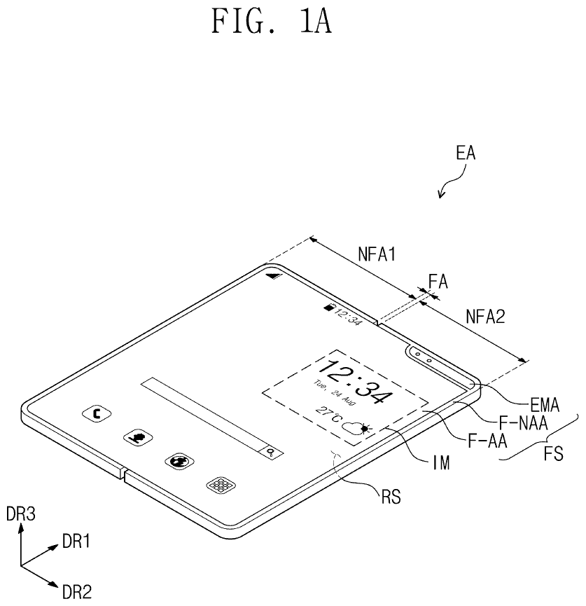

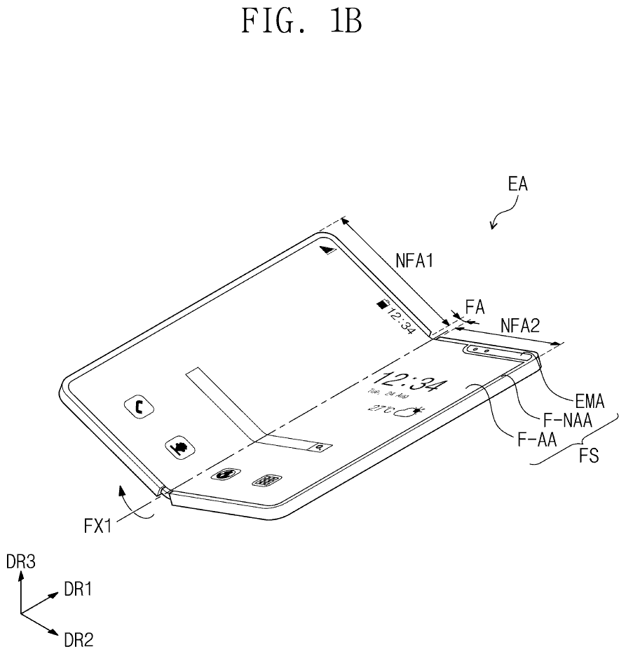

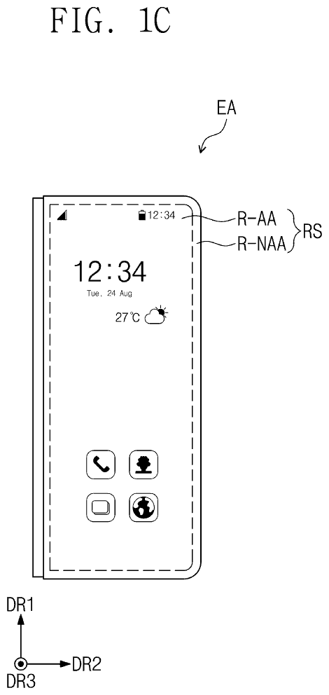

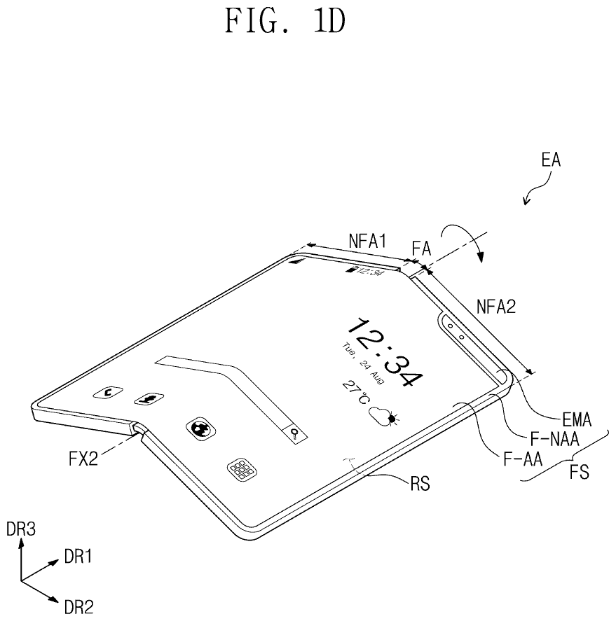

Hereinafter, a display device according to an embodiment of the inventive concept will be described with reference to the drawings. FIG. 1A is a perspective view of a state in which a display device EA according to an embodiment is unfolded.

The display device EA according to an embodiment may be activated in response to an electrical signal. For example, the display device EA may be a mobile phone, a tablet computer, a car navigation system, a game console, or a wearable device, but embodiments supported by the present disclosure are not limited thereto. FIG. 1A and other figures provided herein illustrate an example in which the display device EA is a mobile phone.

The display device EA may include a first display surface FS defined by a first directional axis DR1 and a second directional axis DR2 crossing the first directional axis DR1. The display device EA may supply an image IM to a user through the first display surface FS. The display device EA may display the image IM in a direction with respect to a third directional axis DR3 on the first display surface FS parallel to each of the first directional axis DR1 and the second directional axis DR2.

In the present disclosure, the first directional axis DR1 and the second directional axis DR2 are orthogonal to each other, and the third directional axis DR3 may be a normal direction of a plane defined by the first directional axis DR1 and the second directional axis DR2. A thickness direction of the display device EA may be parallel to the third directional axis DR3. A front surface (or upper surface) and a rear surface (or lower surface) may be opposed to each other in a direction parallel to the third directional axis DR3, and a normal direction of each of the front surface (or upper surface) and the rear surface (or lower surface) may be parallel to the third directional axis DR3. The front surface (or upper surface) means a surface adjacent to the first display surface FS, and the rear surface (or lower surface) means a surface spaced apart from the first display surface FS. In some aspects, the rear surface (or lower surface) means a surface close to a second display surface RS to be described later. An upper side means a direction getting closer to the first display surface FS, and a lower side means a direction getting farther from the first display surface FS.

A cross-section means a surface parallel to a thickness direction (e.g., third directional axis DR3), and a plane means a surface orthogonal to the third directional axis DR3. The plane means a plane defined by the first directional axis DR1 and the second directional axis DR2.

Directions indicated by the first to third directional axes DR1, DR2, and DR3 described in the present disclosure are relative concepts, and may be changed to other directions. In some aspects, the directions indicated by the first to third directional axes DR1, DR2, and DR3 may be described as first to third directions, and the same reference numerals and symbols may be used.

The display device EA may sense an external input applied from the outside. The external input may include various forms of inputs supplied from the outside. For example, the external input may include a contact by a part of a user's body such as, for example, a user's hand, and also an external input (for example, hovering) applied proximate or adjacent to the display device EA within a predetermined distance. In some aspects, the external input may have various forms such as, for example, force, pressure, temperature, and light.

The display device EA may include the first display surface FS and the second display surface RS. The first display surface FS may include a first active region F-AA and a first peripheral region F-NAA, and an electronic module region EMA. The second display surface RS may be defined as a surface opposed to at least a portion of the first display surface FS. That is, the second display surface RS may be defined as a portion of the rear surface of the display device EA.

The active region F-AA may be activated in response to an electrical signal. The active region F-AA may be a region in which the image IM may be displayed, and the external input having various forms may be sensed.

The first peripheral region F-NAA may be adjacent to the first active region F-AA. The first peripheral region F-NAA may have a predetermined color. The first peripheral region F-NAA may surround the first active region F-AA. Accordingly, a shape of the first active region F-AA may be substantially defined by the first peripheral region F-NAA. However, this is an example, and the first peripheral region F-NAA may be disposed adjacent to a single side of the first active region F-AA, and may be omitted.

Various electronic modules may be disposed in the electronic module region EMA. For example, the electronic modules may include at least any one of a camera, a speaker, a light-sensing sensor, or a heat-sensing sensor. The electronic module region EMA may sense an external body received through the display surfaces FS and RS, or may supply a sound signal such as, for example, a voice to the outside through the display surfaces FS and RS. The electronic module may include a plurality of configurations, and is not limited to any one embodiment.

The electronic module region EMA may surround the first peripheral region F-NAA. However, this is an example, and the electronic module region EMA is not limited to any one embodiment. For example, the electronic module region EMA may be surrounded by the first active region F-AA and the first peripheral region F-NAA, and may be disposed in the first active region F-AA.

The display device EA according to an embodiment may include at least one folding region FA, and a plurality of non-folding regions NFA1 and NFA2 extending from the folding region FA. For example, a first non-folding region NFA1, the folding region FA, and a second non-folding region NFA2 may be defined along the second direction DR2. The display device EA according to an embodiment may include the first non-folding region NFA1 and the second non-folding region NFA2 spaced apart from each other in the second direction DR2, with the folding region FA between the first non-folding region NFA1 and the second non-folding region NFA2. For example, the first non-folding region NFA1 may be disposed on one side of the folding region FA along the second direction DR2, and the second non-folding region NFA2 may be disposed on the other side of the folding region FA along the second direction DR2.

FIG. 1A and other figures herein illustrate an embodiment of the display device EA including one folding region FA, but embodiments supported by the present disclosure are not limited thereto. For example, a plurality of folding regions may be defined in the display device EA. In an example, the display device EA according to an embodiment may include at least two folding regions FA, and in some cases, the display device EA may also include at least three non-folding regions disposed with each of the folding regions between the non-folding regions.

FIG. 1B is a perspective view illustrating a folding operation of the display device EA according to an embodiment. FIG. 1C is a plan view of a state in which the display device EA according to an embodiment is folded. FIG. 1D is a perspective view illustrating a folding operation of the display device EA according to an embodiment.

Referring to FIG. 1B, the display device EA according to an embodiment may be folded with respect to a first folding axis FX1 extending in the first direction DR1. In a state in which the display device EA is folded, the folding region FA may have predetermined curvature and radius of curvature. The display device EA may be folded with respect to the first folding axis FX1 such that the first non-folding region NFA1 and the second non-folding region NFA2 face each other, and the display device EA may be deformed to an in-folded state such that the first display surface FS is not exposed to the outside.

Referring to FIG. 1C, in a state in which the display device EA according to an embodiment is in-folded, the second display surface RS may be viewed by a user. In this case, the second display surface RS may include a second active region R-AA that displays an image. The second active region R-AA may be activated in response to an electrical signal. The second active region R-AA may be a region on which the image may be displayed, and which may sense an external input having various forms.

The second peripheral region R-NAA may be adjacent to the second active region R-AA. The second peripheral region R-NAA may have a predetermined color. The second peripheral region R-NAA may surround the second active region R-AA. In some aspects, although not illustrated, the display device EA may also further include, in the second display surface RS, an electronic module region in which an electronic module including various configurations is disposed, and is not limited to any one embodiment.

Referring to FIG. 1D, the display device EA according to an embodiment may be folded with respect to a second folding axis FX2 extending in the first direction DR1. The display device EA may be folded with respect to the second folding axis FX2 to be deformed to an out-folded state in which the first display surface FS is exposed to the outside. In an embodiment, the display device EA may be configured to mutually repeat an in-folding operation and an out-folding operation by a folding operation, but is not limited thereto.

FIGS. 1A to 1D illustrate examples in which the display device EA is folded with respect to one folding axis FX1 or FX2, but the number of the folding axis and the number of the non-folding regions according to the number of the folding axis are not limited thereto. For example, the display device EA may be folded with respect to a plurality of folding axes such that the first display surface FS and the second display surface RS may partially face each other. In some aspects, it is illustrated that the first and second folding axes FX1 and FX2 are parallel to a long side of the display device EA, but embodiments supported by the present disclosure are not limited thereto, and the first and second folding axes FX1 and FX2 may be parallel to a short side of the display device EA.

In the display device EA, the first non-folding region NFA1 and the second non-folding region NFA2 may be defined as portions having display surfaces FS and RS parallel to a plane defined by the first directional axis DR1 and the second directional axis DR2 in a folded state like what is illustrated in FIG. 1C, and the folding region FA may be defined as a region between the first non-folding region NFA1 and the second non-folding region NFA2. The folding region FA may include a curved portion bended so as to have a predetermined curvature in a folded state.

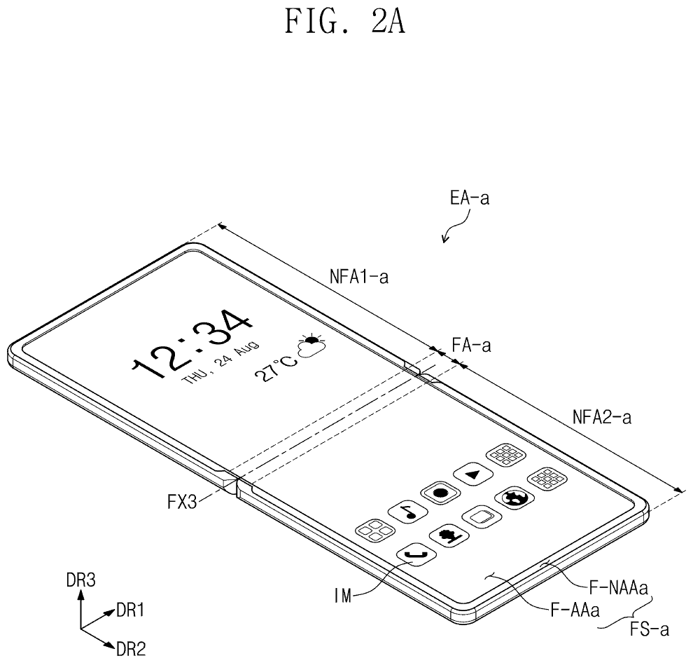

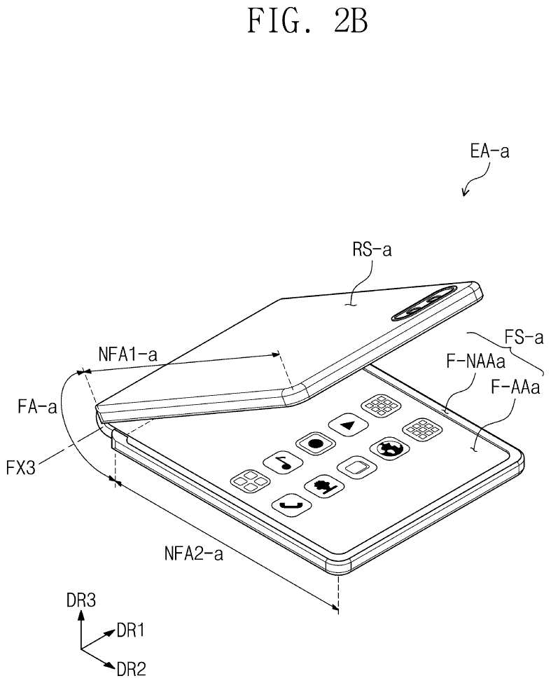

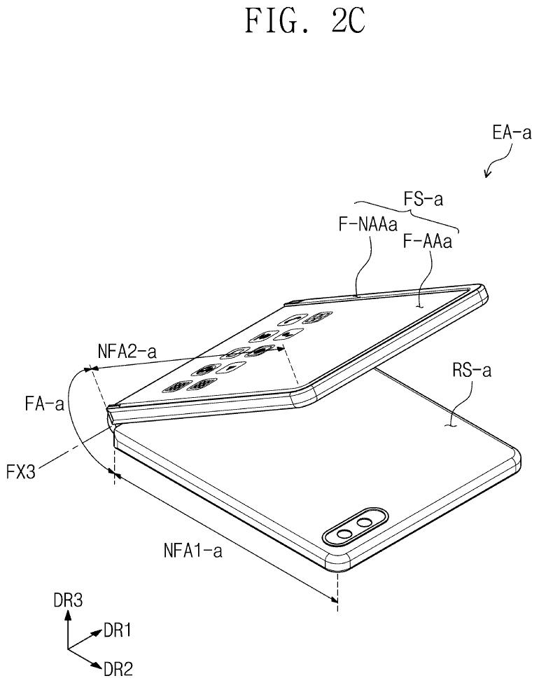

FIGS. 2A to 2C are perspective views illustrating a display device EA-a according to another embodiment of the inventive concept. FIG. 2A is a perspective view illustrating a state in which the display device EA-a is unfolded. FIGS. 2B and 2C are perspective views illustrating a folding operation of the display device EA-a. FIG. 2B is a perspective view illustrating an in-folding operation of the display device EA-a illustrated in FIG. 2A. FIG. 2C is a perspective view illustrating an out-folding operation of the display device EA-a illustrated in FIG. 2A.

The display device EA-a may be folded with respect to the third folding axis FX3 parallel to the first directional axis DR1. Referring to FIG. 2A, an extension direction of the third folding axis FX3 may be parallel to an extension direction of a short side of the display device EA-a.

The display device EA-a may be divided into a folding region FA-a, a first non-folding region NFA1-a adjacent to one side of the folding region FA-a, and a second non-folding region NFA2-a adjacent to the other side of the folding region FA-a. The first non-folding region NFA1-a and the second non-folding region NFA2-a may be spaced apart from each other with the folding region FA-a between the first non-folding region NFA1-a and the second non-folding region NFA2-a.

The folding region FA-a may be folded with respect to the third folding axis FX3. In a state in which the display device EA-a is folded, the folding region FA-a may have predetermined curvature and radius of curvature. The first non-folding region NFA1-a and the second non-folding region NFA2-a may face each other, and the display device EA-a may be in-folded such that the display surface FS-a is not exposed to the outside.

Referring to FIG. 2A, in a state in which the display device EA-a according to an embodiment is not folded (that is, an unfolded state), the display surface FS-a may be displayed to or viewed by a user. As described with reference to FIGS. 1A to 1D, the display surface FS-a of the display device EA-a may include an active region F-AAa and a peripheral region F-NAAa. The active region F-AAa may be a region on which the image IM is displayed, and which may sense an external input having various forms.

Referring to FIG. 2B, in a state in which the display device EA-a according to an embodiment is in-folded, a rear surface RS-a may be displayed to or viewed by a user. For example, the rear surface RS-a may function as a second display surface that displays an image. In some aspects, an electronic module region in which an electronic module including various configurations is disposed may be also disposed in the rear surface RS-a.

Referring to FIG. 2C, the display device EA-a may be folded with respect to the third folding axis FX3 to be deformed to an out-folded state in which of the rear surface RS-a, one region overlapping the first non-folding region NFA1-a and the other region overlapping the second non-folding region NFA2-a face each other.

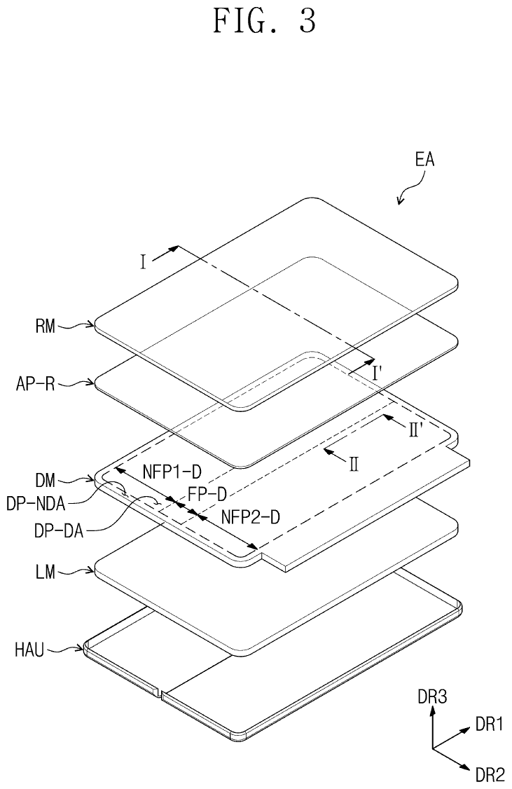

FIG. 3 is an exploded perspective view of the display device EA illustrated in FIG. 1A. Description for the display device EA may be identically applied to the display device EA-a illustrated in FIGS. 2A to 2C.

FIG. 3 is an exploded perspective view illustrating the display device EA according to an embodiment. Referring to FIG. 3, the display device EA may include a display module DM and a protective member RM disposed on the display module DM. In some aspects, the display device EA may further include a lower module LM and a housing HAU.

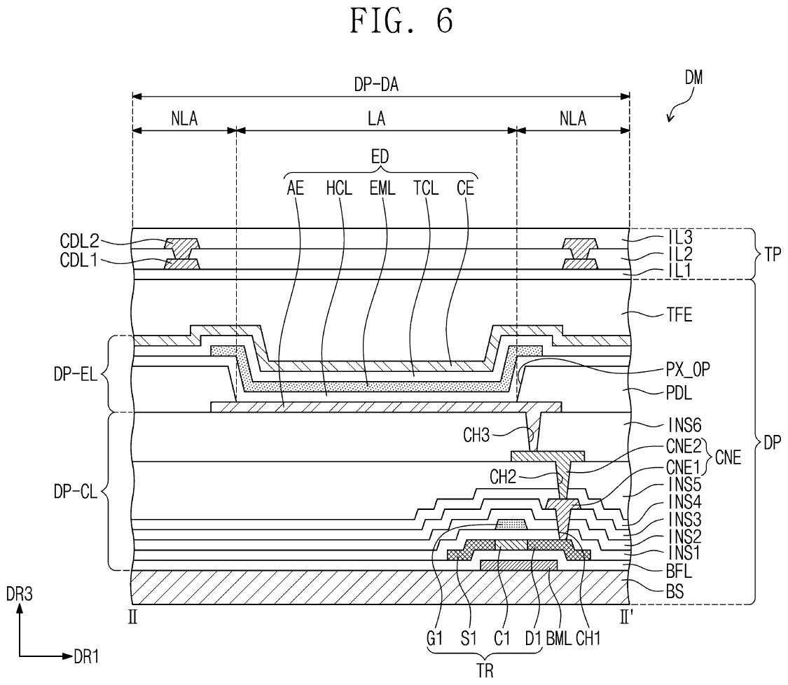

The protective member RM may be of a configuration in which the protective member RM is disposed on the uppermost portion of the display device EA. The image IM (see FIG. 1A) generated by the display module DM may pass through the protective member RM to be supplied to a user. The protective member RM may absorb ultraviolet light of ultraviolet A (UVA) and prevent reflection of external light, and thus may prevent damage to a light-emitting element ED (see FIG. 6) to be described later. The ultraviolet light of UVA may mean ultraviolet light having a wavelength region of about 315 nm to about 400 nm. In some aspects, the protective member RM may protect the display module DM from an external impact, and the protective member may exhibit characteristics of a low curvature in which folding and unfolding may be easily repeated. Accordingly, in an embodiment, the display device EA including the protective member RM may exhibit excellent display quality and reliability.

An upper adhesive layer AP-R may be disposed between the display module DM and the protective member RM. The protective member RM and the display module DM may be coupled through the upper adhesive layer AP-R. The upper adhesive layer AP-R may include a pressure sensitive adhesive (PSA), an optically clear adhesive (OCA) film, or an optically clear adhesive resin (OCR) layer. However, this is an example, and embodiments supported by the present disclosure are not limited thereto. Additional or alternative to the example illustrated, the upper adhesive layer AP-R may be omitted.

The display module DM may display an image in response to an electrical signal and may transmit/receive information about an external input. The display module DM may be divided into a display region DP-DA and a non-display region DP-NDA. The display region DP-DA may be defined as a region from which the image supplied by the display module DM is output. The display region DP-DA of the display module DM may correspond to at least a portion of the active region F-AA (see FIG. 1A).

The non-display region DP-NDA may be adjacent to the display region DP-DA. For example, the non-display region DP-NDA may surround the display region DP-DA. However, this is an example, and the non-display region DP-NDA may be defined in various shapes, and is not limited to any one embodiment.

The display module DM may include a folding display portion FP-D and non-folding display portions NFP1-D and NFP2-D. The folding display portion FP-D may correspond to the folding region FA (see FIG. 1A), and the non-folding display portions NFP1-D and NFP2-D may correspond to the non-folding regions NFA1 and NFA2 (see FIG. 1A).

The folding display portion FP-D may be folded with respect to the folding axes FX1 and FX2 (see FIGS. 1B and 1D). The non-folding display portions NFP1-D and NFP2-D may include a first non-folding display portion NFP1-D and a second non-folding display portion NFP2-D. The first non-folding display portion NFP1-D and the second non-folding display portion NFP2-D may be spaced apart from each other in the second direction DR2 with the folding display portion FP-D between the first non-folding display portion NFP1-D and the second non-folding display portion NFP2-D. The first non-folding display portion NFP1-D may correspond to the first non-folding region NFA1 (see FIG. 1A). The second non-folding display portion NFP2-D may correspond to the second non-folding region NFA2 (see FIG. 1A).

The lower module LM may be disposed under the display module DM. The housing HAU may be disposed under the lower module LM. The housing HAU may include a relatively highly rigid material. For example, the housing HAU may include a plurality of frames and/or plates composed of glass, plastic, or metal. The housing HAU may provide a predetermined accommodation space. The display module DM may be accommodated in the accommodation space such that the display module DM is protected from an external impact.

Although not illustrated, the display device EA may further include an upper film disposed between the display module DM and the protective member RM. The upper film may include a synthetic resin film. The upper film may absorb an external impact applied to the front surface of the display device EA.

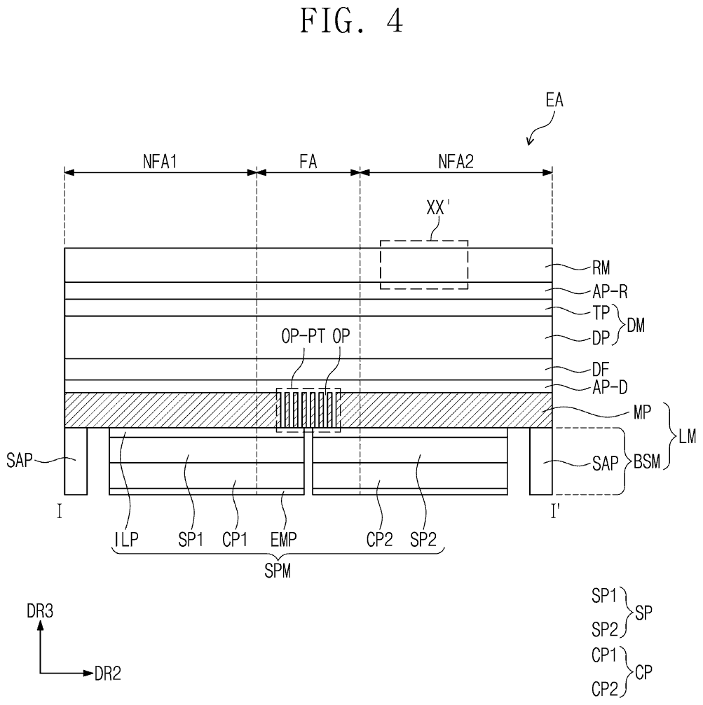

FIG. 4 is a cross-sectional view illustrating a portion corresponding to line I-I′ in FIG. 3. FIG. 4 is a cross-sectional view illustrating a display device EA according to an embodiment. For convenience of description, FIG. 4 illustrates a configuration of the display device EA in which a housing HAU is omitted.

Referring to FIG. 4, a lower module LM may include a supporting plate MP and a lower supporting member BSM. A configuration of the lower module LM illustrated in FIG. 4 is an example, and a combination of configurations included in the lower module LM in the display device EA according to an embodiment may be changed according to a size, a shape, or operation characteristics of the display device EA.

The supporting plate MP may be disposed under the display module DM. The supporting plate MP may include a metal material or a polymer material. For example, the supporting plate MP may be formed including stainless steel, aluminum, or an alloy thereof. Alternatively, or additionally, the supporting plate MP may be formed of the polymer material. A plurality of openings OP may be defined in the supporting plate MP. The supporting plate MP may include an opening pattern OP-PT in which the plurality of openings OP are defined. The opening pattern OP-PT may be formed in the folding region FA.

The lower supporting member BSM may include a supporting member SPM and a filling portion SAP. On a plane, the supporting member SPM may be of a configuration in which the supporting member SPM is overlapping most region of the display module DM. The filling portion SAP may be of a configuration in which the filling portion SAP is disposed outside the supporting member SPM, and overlapping the outskirts (e.g., boundaries or periphery) of the display module DM.

The supporting member SPM may include at least one of a supporting layer SP, a cushion layer CP, a shielding layer EMP, and an interlayer-adhesive layer ILP. A configuration of the supporting member SPM illustrated in FIG. 4 is an example, and embodiments supported by the present disclosure are not limited thereto. For example, one or more of the supporting layer SP, the cushion layer CP, the shielding layer EMP, and the interlayer-adhesive layer ILP may be omitted, a stack sequence of the supporting layer SP, the cushion layer CP, the shielding layer EMP, and the interlayer-adhesive layer ILP may be changed to another sequence different from FIG. 4, or an additional configuration as well as the configurations illustrated in FIG. 4 may be further included in the supporting member SPM.

The supporting layer SP may include a metal material or a polymer material. The supporting layer SP may be disposed on a lower side of the supporting plate MP. For example, the supporting layer SP may be a thin-film metal substrate. The supporting layer SP may include a first sub-supporting layer SP1 and a second sub-supporting layer SP2 spaced apart from each other in the second direction DR2. The first sub-supporting layer SP1 and the second sub-supporting layer SP2 may be spaced apart from each other in a region corresponding to the first folding region FA (see FIG. 1A). Since the supporting layer SP is supplied as the first sub-supporting layer SP1 and the second sub-supporting layer SP2 spaced apart from each other in the folding region FA, folding characteristics of the display device EA may be improved.

The cushion layer CP may be disposed on a lower side of the supporting layer SP. The cushion layer CP may prevent a pressed phenomenon and a plastic deformation of the supporting plate MP by external impact and force. The cushion layer CP may improve impact-resistance of the display device EA. The cushion layer CP may include an elastomer such as, for example, a sponge, a foam, or a urethane resin. In some aspects, the cushion layer CP may be formed by including at least one of an acrylic polymer, a urethane-based polymer, a silicone-based polymer, or an imide-based polymer. However, this is an example, and embodiments supported by the present disclosure are not limited thereto.

The cushion layer CP may include a first sub-cushion layer CP1 and a second sub-cushion layer CP2 spaced apart from each other in the second direction DR2. The first sub-cushion layer CP1 and the second sub-cushion layer CP2 may be spaced apart from each other in a portion corresponding to the folding axis FX1 (see FIG. 1A). Since the cushion layer CP is supplied as the first sub-cushion layer CP1 and the second sub-cushion layer CP2 spaced apart from each other in the folding region FA, folding characteristics of the display device EA may be improved.

The shielding layer EMP may be an electromagnetic wave-shielding layer or a heat dissipation layer. In some aspects, the shielding layer EMP may function as an adhesive layer. The interlayer-adhesive layer ILP may bond configurations of the supporting plate MP and the supporting member SPM. The interlayer-adhesive layer ILP may be supplied in a form of an adhesive resin layer or a bonding tape. FIG. 4 illustrates a configuration in which the interlayer-adhesive layer ILP is supplied as two portions spaced apart from each other in a region corresponding to the folding axis FX1 (see FIG. 1A), but embodiments supported by the present disclosure are not limited thereto. Additional or alternative to the example illustrated, the interlayer-adhesive layer ILP may be supplied as a single layer not spaced apart in a region corresponding to the folding axis FX1 (see FIG. 1A).

The filling portion SAP may be disposed outside the supporting layer SP and the cushion layer CP. The filling portion SAP may be disposed between the supporting plate MP and the housing HAU (see FIG. 3). The filling portion SAP may fill a space between the supporting plate MP and the housing HAU (see FIG. 3), and may fix the supporting plate MP (e.g., fix the supporting plate MP to the housing HAU or another component of the display device EA).

The display device EA may further include a lower protective film DF. The lower protective film DF may be disposed between the display module DM and the supporting plate MP. The lower protective film DF may be of a configuration in which the lower protective film DF is disposed under the display module DM and protects the rear surface of the display module DM. The lower protective film DF may entirely overlap the display module DM. The lower protective film DF may include a polymer material. For example, the lower protective film DF may be a polyimde film or a polyethyleneterephthalate film. However, this is an example, and the lower protective film DF is not limited thereto.

A lower adhesive layer AP-D may be disposed between the supporting plate MP and the lower protective film DF. The supporting plate MP and the lower protective film DF may be coupled through the lower adhesive layer AP-D. Non-limiting examples of the lower adhesive layer AP-D include a pressure sensitive adhesive (PSA), an optically clear adhesive (OCA) film, and an optically clear adhesive resin (OCR) layer. However, this is an example, and embodiments supported by the present disclosure are not limited thereto. Additional or alternative to the example illustrated, the lower adhesive layer AP-D may be omitted.

The display module DM may include a display panel DP and an input sensing portion TP disposed on the display panel DP. The display panel DP may be of a configuration in which the display panel DP substantially generates an image.

The input sensing portion TP may sense an external input and change the external input to a predetermined input signal, and the input sensing portion TP may supply the input signal to the display panel DP. For example, the input sensing portion TP may be a touch sensing portion that senses a touch input at the display device EA according to an embodiment. The input sensing portion TP may recognize or sense a user's direct touch, a user's indirect touch, an object's direct touch, an object's indirect touch, or the like.

The input sensing portion TP may sense at least any one of a position and a strength of the touch applied from the outside. In an embodiment, the input sensing portion TP may have various structures or be composed of various materials, and is not limited to any one embodiment. For example, the input sensing portion TP may sense an external input in a capacitive manner. The display panel DP may be supplied with an input signal by the input sensing portion TP and may generate an image corresponding to the input signal.

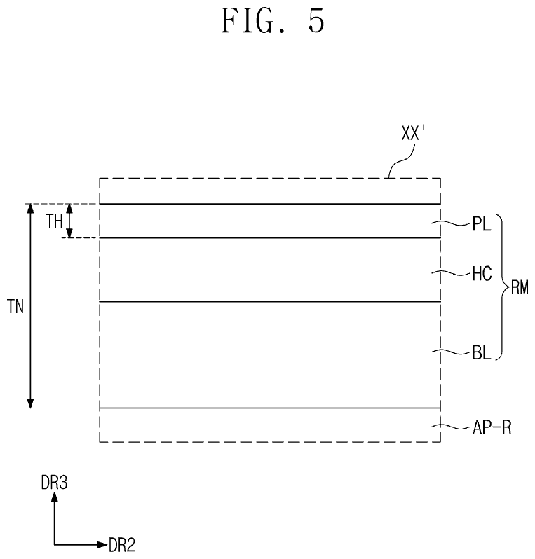

FIG. 5 is an enlarged cross-sectional view illustrating region XX′ in FIG. 4. FIG. 5 is a cross-sectional view specifically illustrating a configuration of a protective member RM.

Referring to FIG. 5, the protective member RM may include a protective base layer BL, a hard coating layer HC disposed on the protective base layer BL, and a protective layer PL disposed on the hard coating layer HC. The protective layer PL may be directly disposed on the hard coating layer HC. The protective layer PL may be disposed on the uppermost portion of the display device EA.

The protective member RM may have a thickness TN of about 60 μm to about 80 μm. In a comparative example, a protective member having a thickness of less than about 60 μm may fail to protect a display module from external impacts, and a protective member having a thickness of greater than about 80 μm may increase a thickness of the display device such that folding reliability of the display device may deteriorate during repetition of folding and unfolding. In contrast, in an embodiment, the protective member RM may have a thickness TN of about 60 μm to about 80 μm, such that the protective member RM may exhibit excellent impact-resistance (e.g., impact-resistance satisfying a threshold) and may maintain the thickness of the display device EA to a level supportive of characteristics in which folding and unfolding may be easily repeated.

The protective base layer BL may be a member supplying a base surface on which the hard coating layer HC and the protective layer PL are disposed. For example, the protective base layer BL may be a flexible polymer film. The protective base layer BL may include at least one of polyethyleneterephthalate, polyimide, polyacrylate, polymethylmethacrylate, polycarbonate, polyethylenenaphthalate, polyvinylidenechloride, polyvinylidenedifluoride, polystyrene, or ethylenevinyalcohol copolymer. The protective base layer BL may have a thickness of about 65 μm. However, this is an example, and the thickness of the protective base layer BL is not limited thereto.

The hard coating layer HC may include a resin for hard coating including at least one of an organic composition, an inorganic composition, or an organic/inorganic composite composition. In some examples, the hard coating layer HC may include a hard coating agent. For example, the hard coating agent forming the hard coating layer HC may be a composition for hard coating including at least one of an acrylic compound, a siloxane compound, or a silesquioxane compound.

In some aspects, the hard coating agent may further include inorganic particles. Supplying the inorganic particles in the hard coating agent may improve hardness of the hard coating layer HC. The inorganic particles may include at least one of SiO₂, TiO₂, Al₂O₃, ZrO₂, ZnO, AlN, or Si₃N₄. The inorganic particles may be surface-treated with an organic material such as, for example, silane so as to increase dispersity in the composition for hard coating. For example, the hard coating layer HC may have a thickness of about 5 μm. However, this is an example, and the thickness of the hard coating layer HC is not limited thereto.

In an embodiment, the protective layer PL may include a base resin including dodecafluoroheptylacrylate (DFHA) having a degree of polymerization of about 8, and the protective layer PL may include a first compound dispersed in the base resin. For example, the first compound may be dispersed in the dodecafluoroheptylacrylate. The first compound may include an azomethine compound.

The base resin of the protective layer PL may be formed by supplying a fluorine-based monomer having low refractive characteristics.

Dodecafluoroheptylacrylate may be the fluorine-based monomer having the low refractive characteristics. Dodecafluoroheptylacrylate having a degree of polymerization of about 8 may be represented as Formula 1 below.

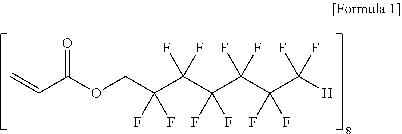

In the protective layer PL, the base resin may have a refractive index of about 1.2 to about 1.4. The dodecafluoroheptylacrylate represented by Formula 1 may have a refractive index of about 1.342. The base resin may further include a material having low refractive characteristics. For example, the material may have a refractive index of about 1.2 to about 1.4. The protective layer PL including the base resin having a refractive index of about 1.2 to about 1.4 may exhibit excellent anti-refractive characteristics.

In the protective layer PL, the base resin and the first compound may have a weight ratio of about 7:3 to about 9:1. The base resin and the first compound may have a weight ratio of about 7:3 to about 9:1 with respect to the total weight of the base resin and the first compound. For example, the base resin and the first compound may have a weight ratio of about 8:2 with respect to the total weight of the base resin and the first compound. In a comparative example, a protective layer in which the base resin and the first compound have a weight ratio of less than about 7:3 with respect to the total weight of the base resin and the first compound includes a small amount of the base resin, and such a protective layer may not exhibit anti-reflective characteristics, and display quality of a display device including the protective layer is deteriorated. In a comparative example, a protective layer PL in which the base resin and the first compound have a weight ratio of more than about 9:1 with respect to the total weight of the base resin and the first compound includes a relatively small amount of the first compound, ultraviolet light having UVA is not absorbed, and damage to a light-emitting element may result due to the ultraviolet light. In contrast, in an embodiment, the protective layer PL in which the base resin and the first compound have a weight ratio of about 7:3 to about 9:1 with respect to the total weight of the base resin and the first compound may exhibit excellent anti-reflective characteristics and excellent ultraviolet light absorbing characteristics.

The first compound may include the azomethine compound. The first compound may include a first sub-compound, and a second sub-compound different from the first sub-compound. The first sub-compound may be the azomethine compound. The second sub-compound may include at least one of a benzotriazole-based compound, a cyanoacrylate-based compound, a benzophenone-based compound, a salicylic acid-based compound, a salicylate-based compound, a cinnamate-based compound, an oxanilide-based compound, a polystyrene-based compound, a polyferrocenylsilane-based compound, a methine compound, a triazine-based compound, a para-aminobenzoic acid-based compound, a cinnamic acid-based compound, or an urocanic acid-based compound. In the present disclosure, “a ˜˜based compound” means a compound including “a functional group of ˜˜”.

The first compound may include a material that absorbs the ultraviolet light having UVA. As described herein, the ultraviolet light having UVA may mean ultraviolet light having a wavelength region of about 315 nm to about 400 nm. In an embodiment, the protective layer PL including the material that absorbs the ultraviolet light having UVA may prevent damage to the light-emitting element ED (see FIG. 6) caused by the ultraviolet light. For example, a light-emitting element including an organic material is vulnerable to the ultraviolet light, and when the ultraviolet light is introduced into the display device, reliability of the display device including the light-emitting element is deteriorated. In contrast, in an embodiment, the protective layer PL including the material that absorbs the ultraviolet light having UVA may prevent damage to the light-emitting element ED (see FIG. 6) caused by the ultraviolet light having UVA, and may improve reliability of the display device EA (see FIG. 4).

In an embodiment, with respect to the total weight in which a first weight of the first sub-compound and a second weight of the second sub-compound are added, the second weight may be greater than the first weight. With respect to the total weight in which the first weight of the first sub-compound and the second weight of the second sub-compound are added, the first sub-compound and the second sub-compound may have a weight ratio of about 1:1.5 to about 1:3.5. For example, the first sub-compound and the second sub-compound may have a weight ratio of about 1:2.5. In a comparative example, a protective layer including the first sub-compound and the second sub-compound that do not satisfy a weight ratio range of about 1:1.5 to about 1:3.5 absorbs light having a different wavelength region, or reduces a degree of absorption of the ultraviolet light, thereby not exhibiting sufficient ultraviolet light absorbing characteristics. In contrast, in an embodiment, the protective layer PL including the first sub-compound and the second sub-compound having a weight ratio of about 1:1.5 to about 1:3.5 may exhibit excellent ultraviolet light absorbing characteristics, thereby improving reliability of the display device EA (see FIG. 4).

In an example, the first sub-compound may be the azomethine compound, and the second sub-compound may be the benzotriazole-based compound. Alternatively, the first sub-compound may be the azomethine compound, and the second sub-compound may be the cyanoacrylate-based compound. The azomethine compound may be represented by Formula 2 below. The azomethine compound represented by Formula 2 illustrates the highest absorption for light having a wavelength region of about 300 nm to about 400 nm in an absorption spectrum. The azomethine compound represented by Formula 2 exhibits an absorption close to 0 (zero) for light having a wavelength region of more than about 410 nm in the absorption spectrum.

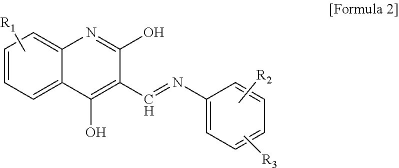

In Formula 2, R₁ may be —[CH₃CH₂CH₂]ₙ₁ (n1 is 1), R₂ may be —[CH₃CH₂O]ₙ₂ (n2 is 6), and R₃ may be —[CH₃COO]n₃ (n3 is 2).

The benzotriazole-based compound may be represented by Formula 3 below. The first compound may include 2-(2′-hydroxy-5-methylphenyl)benzotriazole as the benzotriazole-based compound. The cyanoacrylate-based compound may be represented by Formula 4 below.

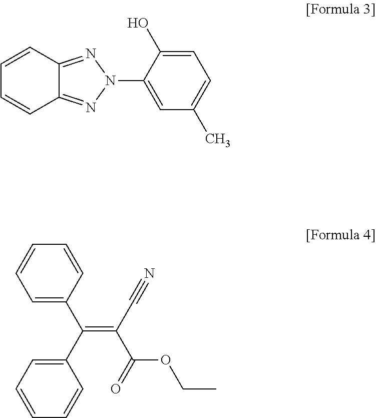 [SMILES: Cc1ccc(O)c(-n2nc3ccccc3n2)c1 ; CCOC(=O)C(C#N)=C(c1ccccc1)c1ccccc1]

The protective layer PL may have a thickness TH of about 0.08 μm to about 0.12 μm. In a comparative example, a protective layer having a thickness of less than 0.08 μm does not have sufficient anti-reflective characteristics and ultraviolet light absorbing characteristics, and thus reliability of the display device is deteriorated. In a comparative example, a protective layer having a thickness of more than about 0.12 μm increases a thickness of the display device, and repetition of folding and unfolding is not easy. In contrast, in an embodiment, the protective layer PL having a thickness of about 0.08 μm to about 0.12 μm exhibits excellent anti-reflective characteristics and excellent ultraviolet light absorbing characteristics, and easy folding and unfolding repetition characteristics. The display device EA (see FIG. 4) including the protective layer PL that satisfies the thickness TH range described herein may have excellent reliability.

In an embodiment, the protective layer PL may have a transmittance equal to or less than about 30% for light having a wavelength region of about 350 nm to about 410 nm. The protective layer PL may have a transmittance equal to or less than about 5% for light having a wavelength of about 405 nm. The light having a wavelength region of about 350 nm to about 410 nm may be included in the ultraviolet light. In the present disclosure, visible light may be defined as light having a wavelength region of more than about 410 nm to about 800 nm.

The protective layer PL including the base resin including dodecafluoroheptylacrylate (DFHA) having a degree of polymerization of about 8 and the first compound dispersed in the base resin may have a transmittance equal to or less than about 30% for the light having a wavelength region of about 350 nm to about 410 nm. In some aspects, the protective layer PL including the base resin including dodecafluoroheptylacrylate (DFHA) having a degree of polymerization of about 8 and the first compound dispersed in the base resin may have a transmittance equal to or less than about 5% for the light having a wavelength of about 405 nm. Since the protective layer PL includes the first compound that absorbs the ultraviolet light, the protective layer PL may exhibit a low transmittance and high absorbing characteristics for the ultraviolet light. Accordingly, the display device EA (see FIG. 4) including the protective layer PL according to an embodiment may have excellent reliability.

In an embodiment, the protective layer PL may have a specular component included (SCI) reflectance of about 0.8 to about 1.8. For example, the protective layer PL may have a SCI reflectance of about 1.35 for light having a wavelength of about 550 nm.

The protective layer PL including the base resin and the first compound described herein may have a SCI reflectance of about 0.8 to about 1.8. The protective layer PL may exhibit a SCI reflectance of about 0.8 to about 1.8 by including the base resin formed of a material having low refractive characteristics. The protective layer PL having a SCI reflectance of about 0.8 to about 1.8 may exhibit excellent anti-reflective characteristics, and may improve display quality of the display device EA (see FIG. 4).

FIG. 6 is a cross-sectional view illustrating a portion corresponding to line II-II′ in FIG. 3. FIG. 6 is a cross-sectional view illustrating a display module DM according to an embodiment.

Referring to FIG. 6, a display panel DP may include a base substrate BS, a circuit layer DP-CL disposed on the base substrate BS, a display element layer DP-EL disposed on the circuit layer DP-CL, and an encapsulation layer TFE that covers the display element layer DP-EL. The display panel DP may substantially generate an image. A configuration of the display panel DP illustrated in FIG. 6 is an example, and the configuration of the display panel DP is not limited thereto.

The base substrate BS may supply a base surface on which the circuit layer DP-CL is disposed. The base substrate BS may be a flexible substrate which is bendable, foldable, rollable, and the like. The base substrate BS may a glass substrate, a metal substrate, a polymer substrate, or the like. However, embodiments supported by the present disclosure are not limited thereto, and the base substrate BS may include an inorganic layer, an organic layer, or a composite material layer.

The base substrate BS may include a single- or multi-layer. For example, the base substrate BS may include a first synthetic resin layer, a single-layered or multi-layered inorganic layer, and a second synthetic resin layer disposed on the single-layered or multi-layered inorganic layer. Each of the first synthetic resin layer and the second synthetic resin layer may include a polyimide-based resin. In some aspects, each of the first synthetic resin layer and the second synthetic resin layer may include at least one of an acrylic resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin. In the present disclosure, “a ˜˜-based resin” means a resin including “a functional group of ˜˜”.

The display panel DP may include a transistor TR and a light-emitting element ED. The transistor TR and the light-emitting element ED may be disposed on the base substrate BS. FIG. 4 illustrates one transistor TR, but the display panel DP may substantially include a plurality of transistors and at least one capacitor for driving the light-emitting element ED.

The circuit layer DP-CL may include an insulating layer, a semiconductor pattern, a conductive pattern, a signal line, and other components supportive of features of the circuit layer DP-CL. For example, the circuit layer DP-CL may include a switching transistor and a driving transistor for driving the light-emitting element ED of the display element layer DP-EL.

The circuit layer DP-CL may include a shielding electrode BML, the transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, a stack structure of the circuit layer DP-CL illustrated in FIG. 6 is an example, and the stack structure of the circuit layer DP-CL may be changed according to a configuration of the display panel DP, a process of the circuit layer DP-CL, and the like.

The shielding electrode BML may be disposed on the base substrate BS. The shielding electrode BML may overlap the transistor TR. The shielding electrode BML may protect the transistor TR by shielding light incident from a lower portion of the display panel DP to the transistor TR. The shielding electrode BML may include a conductive material. In an example in which a voltage is applied to the shielding electrode BML, a threshold voltage of the transistor TR disposed on the shielding electrode BML may be maintained. However, embodiments supported by the present disclosure are not limited thereto, and the shielding electrode BML may be a floating electrode. The shielding electrode BML may be omitted.

The buffer layer BFL may be disposed on the base substrate BS to cover the shielding electrode BML. The buffer layer BFL may include an inorganic layer. The buffer layer BFL may improve a coupling force between a semiconductor pattern or a conductive pattern disposed on the buffer layer BFL, and the base substrate BS.

The transistor TR may include a source S1, a channel C1, a drain D1, and a gate G1. The source S1, the channel C1, and the drain D1 of the transistor TR may be formed from the semiconductor pattern. The semiconductor pattern of the transistor TR may include polysilicon, amorphous silicon, or a metal oxide, and the semiconductor pattern may be implemented with or include any suitable material having a semiconductor property without limitation, and is not limited to any one.

The semiconductor pattern may include a plurality of regions divided according to a magnitude of conductivity. A region, of the semiconductor pattern, doped with dopants, or reduced with a metal oxide may have a great conductivity, and may substantially serve as a source electrode and a drain electrode of the transistor TR. The region, of the semiconductor pattern, having a great conductivity may correspond to the source S1 and the drain D1 of the transistor TR. A region, of the semiconductor pattern, undoped or doped at a low concentration, or not reduced with the metal oxide may have a low conductivity, and may correspond to the channel C1 (or active) of the transistor TR.

While covering the semiconductor pattern of the transistor TR, a first insulating layer INS1 may be disposed on the buffer layer BFL. The gate G1 of the transistor TR may be disposed on the first insulating layer INS1. On a plane, the gate G1 may overlap the channel C1 of the transistor TR. The gate G1 may function as a mask in a process of doping the semiconductor pattern of the transistor TR.

A second insulating layer INS2 may be disposed on the first insulating layer INS1, while covering the gate G1. A third insulating layer INS3 may be disposed on the second insulating layer INS2.

The connection electrode CNE may include a first connection electrode CNE1 and a second connection electrode CNE2 for electrically connecting the transistor TR and the light-emitting element ED. However, a configuration of the connection electrode CNE that electrically connects the transistor TR and the light-emitting element ED is not limited thereto, and one of the first and second connection electrodes CNE1 and CNE2 may be omitted, or an additional connection electrode may be further included.

The first connection electrode CNE1 may be disposed on the third insulating layer INS3. The first connection electrode CNE1 may be connected to the drain D1 through a first contact hole CH1 penetrating the first to third insulating layers INS1 to INS3. A fourth insulating layer INS4 may be disposed on the third insulating layer INS3, while covering the first connection electrode CNE1. A fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 penetrating the fourth and fifth insulating layer INS4 and INS5. A sixth insulating layer INS6 may be disposed on the fifth insulating layer INS5, while covering the second connection electrode CNE2.

Each of the first to sixth insulating layers INS1 to INS6 may include an inorganic layer or organic layer. For example, the inorganic layer may include at least one of aluminum oxide, titanium oxide, silicon oxide, silicon oxynitride, zirconium oxide, or hafnium oxide. The organic layer may include at least one of an acrylic resin, a methacryl-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-EL may include a pixel-defining film PDL and the light-emitting element ED. The light-emitting element ED may include a first electrode AE, a hole control layer HCL, a light-emitting layer EML, an electron control layer TCL, and a second electrode CE. The light-emitting element ED may include at least one organic material. At least one of the hole control layer HCL, the light-emitting layer EML, and the electron control layer TCL may include an organic material. As described herein, the protective layer PL (see FIG. 5) according to an embodiment may exhibit excellent ultraviolet light absorbing characteristics, and thus may prevent (or minimize) a damage caused by the ultraviolet light of the light-emitting element ED including the organic material.

The light-emitting element ED may emit light. For example, the light-emitting element ED may include an organic light-emitting material, an inorganic light-emitting material, an organic-inorganic light-emitting material, a quantum dot, a quantum rod, a micro LED, or a nano LED.

The first electrode AE may be disposed on the sixth insulating layer INS6. The first electrode AE may be connected to the second connection electrode CNE2 through a third contact hole CH3 penetrating the sixth insulating layer INS6. The first electrode AE may be electrically connected to the drain D1 of the transistor TR through the first and second connection electrodes CNE1 and CNE2.

The first electrode AE may be formed of a metal material, a metal alloy, or a conductive compound. The first electrode AE may be an anode or a cathode. However, embodiments supported by the present disclosure are not limited thereto. In some aspects, the first electrode AE may be a pixel electrode. The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of at least two selected therefrom, a mixture of at least two selected therefrom, or an oxide thereof.

In an example in which the first electrode AE is a transmissive electrode, the first electrode AE may include a transparent metal oxide, for example, indium-tin oxide (ITO), indium-zinc oxide (IZO), zinc oxide (ZnO), indium-tin-zinc oxide (ITZO), or the like. In an example in which the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, or a compound or mixture thereof (for example, a mixture of Ag and Mg). Alternatively, the first electrode AE may have a multi-layered structure including a reflective film or semi-transmissive film formed of the above material, and a transparent conductive film formed of indium-tin oxide (ITO), indium-zinc oxide (IZO), zinc oxide (ZnO), indium-tin-zinc oxide (ITZO), or the like. For example, the first electrode AE may have a three-layered structure of ITO/Ag/ITO, but embodiments supported by the present disclosure are not limited thereto. In some embodiments, the first electrode AE may include a metal material described herein, a combination of at least two metal materials selected from the metal materials described herein, an oxide of the metal material described herein, or the like.

The pixel-defining film PDL may be disposed on the sixth insulating layer INS6. A light-emitting opening PX_OP that exposes a portion of the first electrode AE may be defined in the pixel-defining film PDL. The portion of the first electrode AE exposed by the light-emitting opening PX_OP may be defined as a light-emitting region LA.

The display region DP-DA of the display module DM may include the light-emitting region LA and a light-blocking region NLA. A region in which the pixel-defining film PDL is disposed may correspond to the light-blocking region NLA. The light-blocking region NLA may surround the light-emitting region LA in the display region DP-DA.

The hole control layer HCL may be disposed on the first electrode AE and the pixel-defining film PDL. The hole control layer HCL may be provided as a common layer overlapping the light-emitting region LA and the light-blocking region NLA. The hole control layer HCL may include at least one of a hole transport layer, a hole injection layer, or an electron blocking layer. The hole control layer HCL may include a well-known hole injection material and/or a well-known hole transport material.

The light-emitting layer EML may be disposed on the hole control layer HCL. The light-emitting layer EML may be disposed in a region corresponding to the light-emitting opening PX_OP. Alternatively, the light-emitting layer EML may be provided as a common layer. The light-emitting layer EML may include an organic light-emitting material and/or an inorganic light-emitting material. The light-emitting layer EML may emit light having any one color among red, green, and blue. For example, the light-emitting layer EML may emit blue light.

The electron control layer TCL may be disposed on the light-emitting layer EML. The electron control layer TCL may be provided as a common layer overlapping the light-emitting region LA and the light-blocking region NLA. The electron control layer TCL may include at least one of an electron transport layer, an electron injection layer, or a hole blocking layer. The electron control layer TCL may include a well-known electron injection material and/or a well-known electron transport material.

The second electrode CE may be disposed on the electron control layer TCL. The second electrode CE may be provided as a common layer overlapping the light-emitting region LA and the light-blocking region NLA.

The second electrode CE may be a common electrode. The second electrode CE may be a cathode or an anode, but embodiments supported by the present disclosure are not limited thereto. In an example in which the first electrode AE is an anode, the second electrode CE may be a cathode, and when the first electrode AE is a cathode, the second electrode CE may be an anode.

The second electrode CE may be a transmissive electrode, a semi-transmissive electrode, or a reflective electrode. In an example in which the second electrode CE is the transmissive electrode, the second electrode CE may be composed of a transparent metal oxide, for example, indium-tin oxide (ITO), indium-zinc oxide (IZO), zinc oxide (ZnO), indium-tin-zinc oxide (ITZO), or the like.

When the second electrode CE is the semi-transmissive electrode or reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture (for example, AgMg, AgYb, or MgYb) including the same. Alternatively, the second electrode CE may have a multi-layered structure including a reflective film or semi-transmissive film formed of the above material, and a transparent conductive film formed of indium-tin oxide (ITO), indium-zinc oxide (IZO), zinc oxide (ZnO), indium-tin-zinc oxide (ITZO), or the like. For example, the second electrode CE may include a metal material described herein, a combination of at least two metal materials selected from the metal materials described herein, or an oxide of the metal material described herein.

The encapsulation layer TFE may be disposed on the display element layer DP-EL. The encapsulation layer TFE may be disposed on the second electrode CE to cover the light-emitting element ED. The encapsulation layer TFE may protect the display element layer DP-EL from foreign matters such as, for example, moisture, oxygen, and/or dust particles. The encapsulation layer TFE may include a plurality of thin-films.

The encapsulation layer TFE may include at least one inorganic film. For example, the encapsulation layer TFE may include inorganic films disposed on the second electrode CE, and an organic film disposed between the inorganic films. The inorganic film may protect the light-emitting element ED from moisture/oxygen, and the organic film may protect the light-emitting element ED from foreign matters such as, for example, dust particles.

An input sensing portion TP may be disposed on the display panel DP. For example, the input sensing portion TP may be directly disposed on the encapsulation layer TFE of the display panel DP. Alternatively, an adhesive layer may be disposed between the input sensing portion TP and the display panel DP.

In the present disclosure, “one component is directly disposed/provided on another component” means that a third component is not disposed/provided between the one component and the other component. That is, one component is ‘directly disposed/provided’ on another component means that the one component is in ‘contact’ with the other component.

The input sensing portion TP may include a first sensing insulating layer IL1, a second sensing insulating layer IL2, and a third sensing insulating layer IL3. The input sensing portion TP may include at least one conductive layer disposed on the sensing insulating layers. The input sensing portion TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may be in contact with the encapsulation layer TFE. Alternatively, the first sensing insulating layer IL1 may be omitted, and in this case, the first conductive layer CDL1 may be in contact with the encapsulation layer TFE.

The first conductive layer CDL1 may be disposed on the first sensing insulating layer ILL. The first conductive layer CDL1 may include a plurality of first conductive patterns. The plurality of first conductive patterns may be disposed on the first sensing insulating layer ILL. The second sensing insulating layer IL2 may be disposed on the first sensing insulating layer IL1 so as to at least partially cover the first conductive layer CDL1.

The second conductive layer CDL2 may be disposed on the second sensing insulating layer IL2. The second conductive layer CDL2 may include a plurality of second conductive patterns. The plurality of second conductive patterns may be disposed on the second sensing insulating layer IL2. The plurality of second conductive patterns may be respectively connected to the plurality of first conductive patterns through a contact hole formed in the second sensing insulating layer IL2.

Each of the plurality of first conductive patterns of the first conductive layer CDL1 and the plurality of second conductive patterns of the second conductive layer CDL2 may be disposed corresponding to the light-blocking region NLA. Each of the plurality of first conductive patterns of the first conductive layer CDL1 and the plurality of second conductive patterns of the second conductive layer CDL2 may correspond to a mesh pattern.

The third sensing insulating layer IL3 may be disposed on the second sensing insulating layer IL2, and may cover the second conductive layer CDL2. Each of the second sensing insulating layer IL2 and the third sensing insulating layer IL3 may include an inorganic insulating layer and an organic insulating layer.

The first conductive layer CDL1 and the second conductive layer CDL2 may each have a single-layered structure, or may have a stacked multi-layered structure along the third direction DR3. The conductive layers CDL1 and CDL2 having a single-layered structure may include a metal layer or transparent conductive layer. The metal layer may include molybdenum, silver, titanium, copper, aluminum, or an alloy thereof. The transparent conductive layer may include a transparent conductive oxide such as, for example, indium-tin oxide (ITO), indium-zinc oxide (IZO), zinc oxide (ZnO), or indium-tin-zinc oxide (ITZO). In some aspects, the transparent conductive oxide may include a conductive polymer such as, for example, PEDOT, metal nanowire, graphene, or the like.

The conductive layers CDL1 and CDL2 having a multi-layered structure may include metal layers. For example, the metal layers may have a three-layered structure of titanium (Ti)/aluminum (Al)/titanium (Ti). The conductive layers CDL1 and CDL2 having a multi-layered structure may have at least one metal layer and at least one transparent conductive layer.

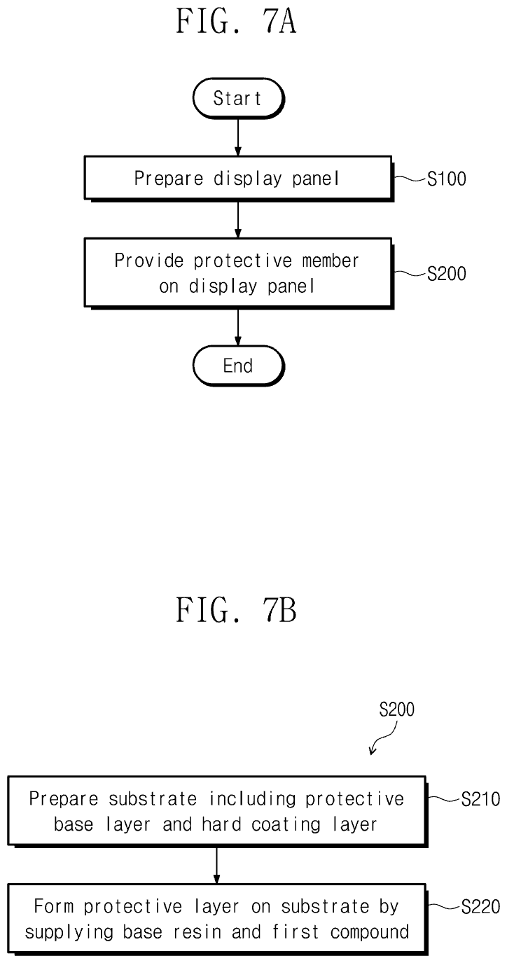

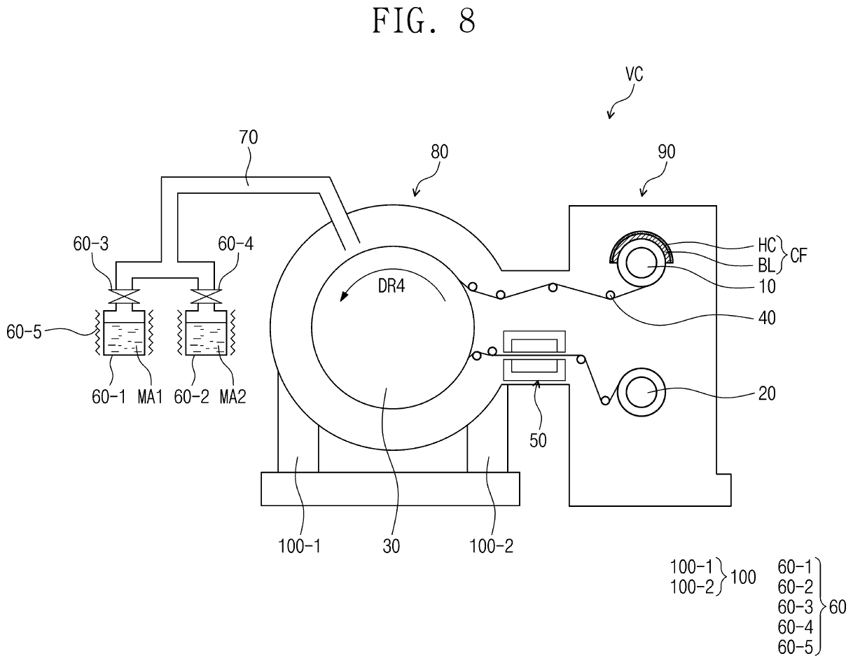

Example aspects of a method and processes supported by aspects of the present disclosure are described with reference to FIGS. 7A, 7B, and 8. In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

A display device according to an embodiment may be formed in a method for manufacturing a display device according to an embodiment. FIGS. 7A and 7B are flowcharts illustrating operations of manufacturing a display device according to an embodiment. FIG. 8 is a diagram schematically illustrating an operation of manufacturing a display device according to an embodiment. Hereinafter, in describing FIG. 7A to FIG. 8, description duplicated with those made with reference to FIGS. 1A to 6 will not be made again, and differences will be mainly described.

Referring to FIG. 7A, the method for manufacturing a display device according to an embodiment may include an operation (S100) of preparing a display panel and an operation (S200) of supplying (providing) a protective member on the display panel. The display panel DP (see FIG. 4) may be foldable with respect to at least one folding axis FX1 or FX2 (see FIGS. 1B and 1D). The protective member RM (see FIG. 5) may include the protective base layer BL (see FIG. 5), the hard coating layer HC (see FIG. 5) disposed on the protective base layer BL (see FIG. 5), and the protective layer PL (see FIG. 5) disposed on the hard coating layer HC (see FIG. 5). Referring to FIG. 7B, the operation (S200) of supplying a protective member may include an operation (S210) of preparing a substrate including the protective base layer BL and the hard coating layer HC and an operation (S220) of forming the protective layer PL by supplying a base resin and a first compound on the substrate.

FIG. 8 is a diagram illustrating an operation of forming the protective member RM (see FIG. 5) according to an embodiment. Referring to FIG. 8, the operation may include using a vacuum deposition polymerization device VC in association with forming the protective member RM (see FIG. 5).

The vacuum deposition polymerization device VC may include a main body 90, a vacuum tank 80, a pipe 70, a source unit 60, and a support portion 100. The vacuum tank 80 is connected to the main body 90, and the pipe 70 is disposed between the vacuum tank 80 and the source unit 60, such that a material may be supplied from the source unit 60 to the vacuum tank 80 through the pipe 70. The support portion 100 may include a first sub-support portion 100-1 and a plurality of second sub-support portions 100-2 disposed on the first sub-support portion 100-1. The second sub-support portions 100-2 may be disposed between the vacuum tank 80 and the first sub-support portion 100-1. The support portion 100 may be configured such that the support portion 100 supports the vacuum tank 80. The configuration of the vacuum deposition polymerization device VC illustrated in FIG. 8 is an example, and embodiments supported by the present disclosure are not limited thereto.

A first roller 10 and a second roller 20 spaced apart from the first roller 10 in one direction may be disposed in the main body 90. The first roller 10 may be disposed in an upper portion of the main body 90, and the second roller 20 may be disposed in a lower portion of the main body 90. The first roller 10 and the second roller 20 may rotate clockwise.

A main roller 30 may be disposed between the first roller 10 and the second roller 20. The main roller 30 may be disposed in the vacuum tank 80. The pipe 70 may be disposed adjacent to the main roller 30. The main roller 30 may rotate in a fourth direction DR4, and the fourth direction DR4 may be a counterclockwise direction. A plurality of sub-rollers 40 may be disposed between the first roller 10 and the main roller 30, and a plurality of sub-rollers 40 may be disposed between the second roller 20 and the main roller 30. The sub-roller 40 may be a tension roller. A substrate CF may be supplied on the first roller 10, and the vacuum deposition polymerization device VC may move the substrate CF along the main roller 30 and the sub-roller 40 in association with disposing the substrate CF on the second roller 20. The substrate CF disposed on the second roller 20 may be the substrate CF on which the protective layer PL (see FIG. 5) is formed. The substrate CF may include the protective base layer BL and the hard coating layer HC.

The source unit 60 may supply a first source material MA1 and a second source material MA2 on the substrate CF moving along the main roller 30. The source unit 60 may supply the first source material MA1 and the second source material MA2 such that the protective layer PL (see FIG. 5) is formed on the substrate CF. The source unit 60 may include a first source portion 60-1, a second source portion 60-2, a first valve 60-3, a second valve 60-4, and a heater 60-5.

The first source portion 60-1 may supply the first source material MA1, and the second source portion 60-2 may supply the second source material MA2. The first valve 60-3 may be connected to the first source portion 60-1 and control supply of the first source material MA1, and the second valve 60-4 may be connected to the second source portion 60-2 and control supply of the second source material MA2. The heater 60-5 may be disposed on both sides of each of the first source portion 60-1 and the second source portion 60-2 and provide an environment of a target temperature, such that the vacuum deposition polymerization device VC may supply the first source material MA1 and the second source material MA2 according to the targeted temperature.

The first source material MA1 may be a material for supplying the base resin, and the second source material MA2 may be a material for supplying the first compound. The first source material MA1 and the second source material MA2 may be supplied according to a weight ratio of about 7:3 to about 9:1, with respect to the total weight of the first source material MA1 and the second source material MA2.

The first source material MA1 may include dodecafluoroheptylacrylate, which is a fluorine-based monomer having low refractive characteristics. The second source material MA2 may include a single material or a plurality of materials. The second source material MA2 may include an azomethine compound as the single material. Alternatively, the second source material MA2 may include, as the plurality of materials, a first sub-compound and a second sub-compound. The first sub-compound and the second sub-compound may be mixed in a weight ratio of about 1:1.5 to about 1:3.5 with respect to the total weight of the first sub-compound and the second sub-compound, and may be supplied.

The first sub-compound may be the azomethine compound. The second sub-compound may include at least one of a benzotriazole-based compound, a cyanoacrylate-based compound, a benzophenone-based compound, a salicylic acid-based compound, a salicylate-based compound, a cinnamate-based compound, an oxanilide-based compound, a polystyrene-based compound, a polyferrocenylsilane-based compound, a methine-based compound, a triazine-based compound, a para-aminobenzoic acid-based compound, a cinnamic acid-based compound, or an urocanic acid-based compound. In some aspects, the first source material MA1 may further include a monomer having low refractive characteristics in a range in which the low refractive characteristics of the protective layer PL is not deteriorated.

The method may include forming the protective layer PL by a dry process. Forming the protective layer PL may include supplying the first source material MA1 and the second source material MA2 at an ion acceleration voltage of about 100 V to about 500 V. The method may include supplying the base resin and the first compound at the ion acceleration voltage of about 100 V to about 500 V. For example, the method may include supplying the base resin and the first compound at an ion acceleration voltage of about 300 V. In a comparative example in which the base resin and the first compound are supplied at an ion acceleration voltage of less than about 100 V, the protective layer is not easily formed, and in a comparative example in which the base resin and the first compound are supplied at an ion acceleration voltage of more than about 500 V, a protective layer having a low wear-resistance is formed. In contrast, the method for manufacturing a display device according to an embodiment including the operation of providing the base resin and the first compound at the ion acceleration voltage of about 100 V and about 500 V may exhibit excellent manufacturing reliability. The protective layer PL (see FIG. 5) formed from the base resin and the first compound supplied at the ion acceleration voltage of about 100 V to about 500 V may exhibit excellent wear-resistance and excellent adhesion to the substrate CF.

The method may include performing the operation of forming the protective layer PL (see FIG. 5) at a temperature of about −30° C. to about 10° C. For example, the method may include performing the operation of forming the protective layer PL (see FIG. 5) at a temperature of about −20° C. In a comparative example in which the protective layer is formed at a temperature of less than about −30° C., the first source material and/or the second source material may have/has a low molecular energy which prevents easily forming the protective layer. In a comparative example in which the protective layer is formed at a temperature of more than about 10° C., a protective layer having a low wear-resistance is formed. In contrast, the method for manufacturing a display device according to an embodiment including the operation of forming the protective layer PL at a temperature of about −30° C. to about 10° C. may exhibit excellent manufacturing reliability.

The method may include forming the base resin from the dodecafluoroheptylacrylate of the first source material MA1, and the method may include dispersing the first compound of the second source material MA2 in the base resin to form a preliminary protective layer. The method may include supplying the preliminary protective layer on the substrate CF to form the protective layer PL (see FIG. 5). The method may include forming and supplying the preliminary protective layer in the same operation. That is, the method may include simultaneously performing polymerization, which is a process of forming the protective layer PL (see FIG. 5), and deposition of the protective layer PL (see FIG. 5). The method may include forming the protective layer PL (see FIG. 5) by directly dispersing the first compound in the base resin on the substrate CF. Accordingly, the method for manufacturing a display device according to an embodiment may exhibit excellent manufacturing efficiency.

In some embodiments, the method for manufacturing a display device according to an embodiment may exhibit characteristics in which the targeted protective layer PL (see FIG. 5) is easily formed according to a form/operation characteristics of the display device by optimizing a temperature of a region (a region on the main roller 30, or the sub-roller 40) in which the substrate CF is disposed in the vacuum deposition polymerization device VC, a speed of forming the protective layer PL (see FIG. 5), a current (for example, an ionic current) for supplying the first compound, or the like.

The vacuum deposition polymerization device VC may include a microwave emission device 50. The microwave emission device 50 may be disposed between the second roller 20 and the main roller 30. The microwave emission device 50 may emit microwaves (and irradiate an object with the microwaves) so as to improve a coupling force between the protective layer PL (see FIG. 5) and the substrate CF formed while moving along the main roller 30. The substrate CF on which the protective layer PL (see FIG. 5) is formed, that is, the protective member RM (see FIG. 5) manufactured in the manufacturing method according to an embodiment may exist on the second roller 20.

The display device according to an embodiment may include a protective member disposed on a display panel. The protective member may include a protective base layer, a hard coating layer, and a protective layer sequentially stacked. The protective layer may include a base resin and a first compound dispersed in the base resin. The base resin may include dodecafluoroheptylacrylate having a degree of polymerization of about 8, and the first compound may include an azomethine compound. Accordingly, the protective layer may exhibit excellent ultraviolet light absorbing characteristics and excellent ultraviolet light absorbing characteristics, and the display device including the protective layer may have excellent reliability.

The display device according to an embodiment may be manufactured in a method for manufacturing a display device according to an embodiment. The method for manufacturing a display device according to an embodiment may include an operation of forming the protective layer, the base resin and the first compound may supplied at the operation of forming the protective layer, and the first compound may be dispersed in the base resin, and at the same time, the protective layer may be formed on the hard coating layer. Accordingly, the method for manufacturing a display device according to an embodiment may exhibit excellent manufacturing efficiency, and the display device having excellent reliability may be manufactured in the method.

A display device according to an embodiment may include a protective layer including an ultraviolet light absorbing material, thereby illustrating excellent reliability.

A method for manufacturing a display device according to an embodiment may include an operation of forming the protective layer by supplying the ultraviolet light absorbing material, thereby manufacturing the display device having excellent reliability.

In the above, description has been made with reference to example embodiments of the inventive concept, but those skilled in the art or those of ordinary skill in the relevant technical field may understand that various modifications and changes may be made to the inventive concept within the scope not departing from the spirit and the technology scope of the inventive concept described in the claims to be described later.

Therefore, the technical scope of the inventive concept is not limited to the contents described in the detailed description of the specification, but should be determined by the claims.

What is claimed is:

1. A display device comprising:
a display panel foldable with respect to at least one folding axis; and
a protective member disposed on the display panel,
wherein the protective member comprises:
a protective base layer;
a hard coating layer disposed on the protective base layer; and
a protective layer disposed on the hard coating layer and comprising:
a base resin comprising dodecafluoroheptylacrylate (DFHA) having a degree of polymerization of about 8; and
a first compound dispersed in the base resin, wherein the first compound comprises an azomethine compound.

2. The display device of claim 1, wherein a weight ratio of the base resin and the first compound is about 7:3 to about 9:1.

3. The display device of claim 1, wherein:
the first compound comprises a first sub-compound, which is the azomethine compound, and a second sub-compound different from the first sub-compound, and
the second sub-compound comprises at least one of a benzotriazole-based compound, a cyanoacrylate-based compound, a benzophenone-based compound, a salicylic acid-based compound, a salicylate-based compound, a cinnamate-based compound, an oxanilide-based compound, a polystyrene-based compound, a polyferrocenylsilane-based compound, a methine-based compound, a triazine-based compound, a para-aminobenzoic acid-based compound, a cinnamic acid-based compound, or an urocanic acid-based compound.

4. The display device of claim 3, wherein with respect to a total weight of a first weight of the first sub-compound and a second weight of the second sub-compound, the second weight is greater than the first weight.

5. The display device of claim 3, wherein a weight ratio of the first sub-compound and the second sub-compound is about 1:1.5 to about 1:3.5.

6. The display device of claim 1, wherein a thickness of the protective layer is about 0.08 μm to about 0.12 μm.

7. The display device of claim 1, wherein a specular component included (SCI) reflectance of the protective layer is about 0.8 to about 1.8.

8. The display device of claim 1, wherein a transmittance of the protective layer is about 30% or less with respect to light having a wavelength region of about 350 nm to about 410 nm.

9. The display device of claim 1, wherein a transmittance of the protective layer is equal to or less than about 5% with respect to light having a wavelength of about 405 nm.

10. The display device of claim 1, wherein the protective base layer comprises at least one of polyethyleneterephthalate, polyimide, polyacrylate, polymethylmethacrylate, polycarbonate, polyethylenenaphthalate, polyvinylidenechloride, polyvinylidenedifluoride, polystyrene, or ethylene-vinylalcohol copolymer.

11. The display device of claim 1, wherein a thickness of the protective member is about 60 μm to about 80 μm.

12. The display device of claim 1, wherein a refractive index of the base resin is about 1.2 to about 1.4.

13. A method for manufacturing a display device, the method comprising:
preparing a display panel foldable with respect to at least one folding axis; and
supplying a protective member on the display panel, the protective member comprising a protective base layer, a hard coating layer disposed on the protective base layer, and a protective layer disposed on the hard coating layer,
wherein the supplying of the protective member comprises:
preparing a substrate comprising the protective base layer and the hard coating layer; and
forming the protective layer on the substrate by supplying:
a base resin comprising dodecafluoroheptylacrylate having a degree of polymerization of about 8, and
a first compound comprising an azomethine compound, and
wherein the protective layer comprises the first compound dispersed in the dodecafluoroheptylacrylate.

14. The method of claim 13, wherein the forming of the protective layer comprises supplying the base resin and the first compound at an ion acceleration voltage of about 100 V to about 500 V.

15. The method of claim 13, wherein the forming of the protective layer comprises:
forming a preliminary protective layer by dispersing the first compound in the base resin; and
depositing the preliminary protective layer on the substrate,
wherein the forming of the preliminary protective layer and the depositing of the preliminary protective layer are performed in the same operation.

16. The method of claim 13, wherein the forming of the protective layer is performed at a temperature of about −30° C. to about 10° C.

17. The method of claim 13, wherein a weight ratio of the base resin and the first compound is about 7:3 to about 9:1.

18. The method of claim 13, wherein:
the first compound comprises a first sub-compound which is the azomethine compound, and a second sub-compound different from the first sub-compound, and
the second sub-compound comprises at least one of a benzotriazole-based compound, a cyanoacrylate-based compound, a benzophenone-based compound, a salicylic acid-based compound, a salicylate-based compound, a cinnamate-based compound, an oxanilide-based compound, a polystyrene-based compound, a polyferrocenylsilane-based compound, a methine-based compound, a triazine-based compound, a para-aminobenzoic acid-based compound, a cinnamic acid-based compound, or an urocanic acid-based compound.

19. The method of claim 18, wherein a weight ratio of the first sub-compound and the second sub-compound is about 1:1.5 to about 1:3.5.

20. The method of claim 13, wherein the protective base layer comprises at least one of polyethyleneterephthalate, polyimide, polyacrylate, polymethylmethacrylate, polycarbonate, polyethylenenaphthalate, polyvinylidenechloride, polyvinylidenedifluoride, polystyrene, or ethylene-vinylalcohol copolymer.
